(19) United States
(12) Patent Application Publication
(10) Pub. No.: US 2011/0149661 A1
(43) Pub. Date: Jun. 23, 2011

(54) MEMORY ARRAY HAVING EXTENDED WRITE OPERATION

(76) Inventors: Iqbal R. Rajwani, Roseville, CA (US); Satish K. Damaraju, El Dorado Hills, CA (US); Niranjan L. Cooray, Folsom, CA (US); Muhammad M. Khellah, Tigard, OR (US); Jaydeep P. Kulkarni, Hillsboro, OR (US)

(21) Appl. No.: 12/642,444

(22) Filed: Dec. 18, 2009

(51) Int. Cl. G11C 7/00; G11C 8/08; G11C 8/18

(52) U.S. Cl. 365/189.11; 365/230.06; 365/233.1; 365/203; 365/207

(57) ABSTRACT

In some embodiments, an apparatus comprising a memory array of static random access memory (SRAM) cells arranged in a plurality of rows and a plurality of columns and configured to receive a clock signal having a plurality of clock cycles; a plurality of word-lines associated with the plurality of rows of the SRAM cells; and a selected word-line driver configured during an extended write operation to drive a selected one of the plurality of word-lines with a write word-line signal having an extended duration. Other embodiments may be described and claimed.

### CROSS-REFERENCE TO RELATED APPLICATION

This application is related to copending U.S. patent application Ser. No. 12/576,868, filed Oct. 9, 2009, entitled “Method and System to Lower the Minimum Operating Voltage of a Memory Array”.

### BACKGROUND

1. Technical Field

Embodiments of the present disclosure are related to the field of integrated circuits, and in particular, to memory.

2. Description of Related Art

Static random access memory (SRAM) often is arranged as a matrix of memory cells fabricated in an integrated circuit (IC) chip, and address decoding in the chip allows access to each cell for read/write operations. SRAM memory cells use active feedback from cross-coupled inverters in the form of a latch to store or “latch” a bit of information. These SRAM memory cells are often arranged in rows so that blocks of data such as words or bytes may be written or read simultaneously. Standard SRAM memory cells have many variations and may be used for cache memory.

Write V_{MIN} or V_{CCMIN} is defined to be the lowest possible operating voltage V_{cc} where a write operation may still occur at a given frequency. There is generally a tradeoff in designing a memory cell to be stable and to be readily written into (high V_{MIN}). Additionally, the higher the V_{MIN}, the more the power consumption. As to ways to improve write V_{MIN}, write V_{MIN} has been provided with larger effective pulse-width (PW) during the write operations by slowing down the frequency at a given V_{MIN}, which may result in wider pulse and hence larger effective PW. Another technique is based upon knowing that writing into memory cell depends on a control signal ratio Xfer1/p1 (or Xfer0/p0), so write V_{MIN} may be improved by upsizing Xfer1 and Xfer2 devices in memory cell. This technique has, however, direct negative impact on cell read stability. Another technique that is widely used to improve write V_{MIN} is V_{CC}-collapse, which temporarily reduces the magnitude of the V_{CC} supply to cross coupled inverters of a selected SRAM cell for write by a given AV. This approach, however, trades the retention stability of unselected SRAM cells sharing the same supply; especially as lower V_{CC} is used (that is, V_{CC}−ΔV becomes close to Vretention).

### BRIEF DESCRIPTION OF THE DRAWINGS

FIG. 1 illustrates a schematic diagram of a memory implementing a write-extension scheme, according to various embodiments of the present disclosure.

FIG. 2 illustrates a more detailed schematic diagram of the memory of FIG. 1 to implement a write-extension scheme and an illustrative memory controller for the memory of FIG. 1, according to some embodiments of the present disclosure.

FIG. 3 illustrates a timing diagram of the memory of FIGS. 1 and 2, according to some embodiments of the present disclosure.

FIG. 4 illustrates a table showing various possibilities for a back-to-back access operation after an extended write operation of FIGS. 1 and 2, according to some embodiments of the present disclosure.

FIG. 5 illustrates a schematic diagram of the memory of FIG. 1 with a plurality of sub-arrays and a charge pump for implementing the write-extension scheme and a read-modify-write scheme, according to some embodiments of the present disclosure.

FIG. 6 illustrates a schematic diagram of a word-line driver with a two-stage, level shifter for use in the memory array of FIGS. 1 and 5, according to some embodiments of the present disclosure.

FIG. 7 illustrates a timing diagram for the level shifter of FIG. 6, according to some embodiments of the present disclosure.

FIG. 8 illustrates a schematic diagram of a per-column sense amplifier for use in the memory of FIGS. 1 and 5, according to some embodiments of the present disclosure.

FIG. 9 illustrates a timing diagram of the memory of FIG. 1 using the per-column sense amplifier of FIG. 8, according to some embodiments of the present disclosure.

FIG. 10 illustrates a method of using the memory of FIG. 1, according to some embodiments of the present disclosure.

FIG. 11 illustrates a system incorporating the memory of FIG. 1, according to some embodiments of the present disclosure.

### DETAILED DESCRIPTION OF ILLUSTRATIVE EMBODIMENTS

In the following description, for purposes of explanation, numerous details are set forth in order to provide a thorough understanding of the disclosed embodiments. However, it will be apparent to one skilled in the art that these specific details are not required in order to practice the disclosed embodiments. In other instances, well-known electrical structures and circuits are shown in block diagram form in order not to obscure the disclosed embodiments. The term “coupled” shall encompass a direct connection, an indirect connection or an indirect communication.

A memory array of SRAM cells, according to the various embodiments of the present disclosure, may be designed to reduce write V_{MIN} at high and/or low frequencies with limited die-size increase and at no significant decrease in circuit performance, while limiting array power dissipation. In some embodiments, the SRAM cells of the memory array may incorporate a write-extension scheme during an extended write operation wherein a write word-line signal (hereafter “write WL signal”) on a selected word-line may be extended from one clock cycle to substantially two clock cycles (a first clock cycle and a second clock cycle) to reduce write V_{MIN} at high frequencies with no or limited performance loss and without the need for additional area growth. In some embodiments, the memory array may be particularly suited for use as cache memory.

In some embodiments, the SRAM cells of the memory array also may incorporate a read-modified-write (RMW) scheme wherein the extended write WL signal may be boosted in the second clock cycle of the extended write WL signal to reduce the write V_{MIN}. Write WL signal boosting may be particularly useful at a low voltage/frequency mode (LFM) as the write-extension scheme does not give significant V_{MIN} reduction in LFM. In some embodiments, the write WL signal boosting may be achieved with an integrated charge pump and 2-stage level shifter. In some embodiments, a per-column sense amplifier (SA) may be shared between array sectors to achieve better area. In some embodiments, the SA may be pulsed with a pulsed sense-amplifier-enable (SAE) signal to limit a bit-line swing during a write-back operation. This may reduce bit-line power dissipation compared to a full bit-line swing write-back.

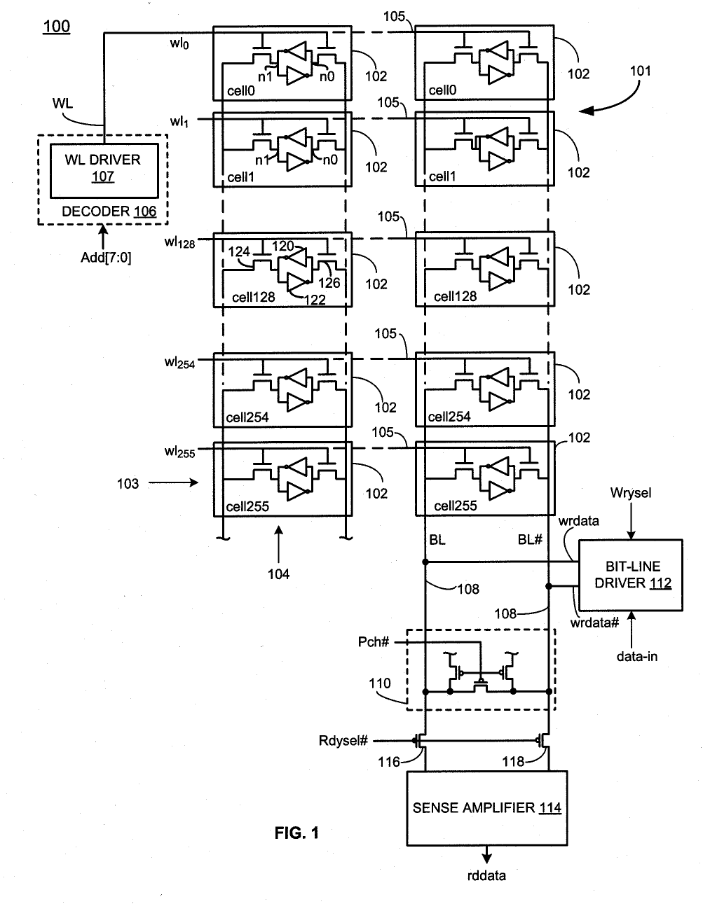

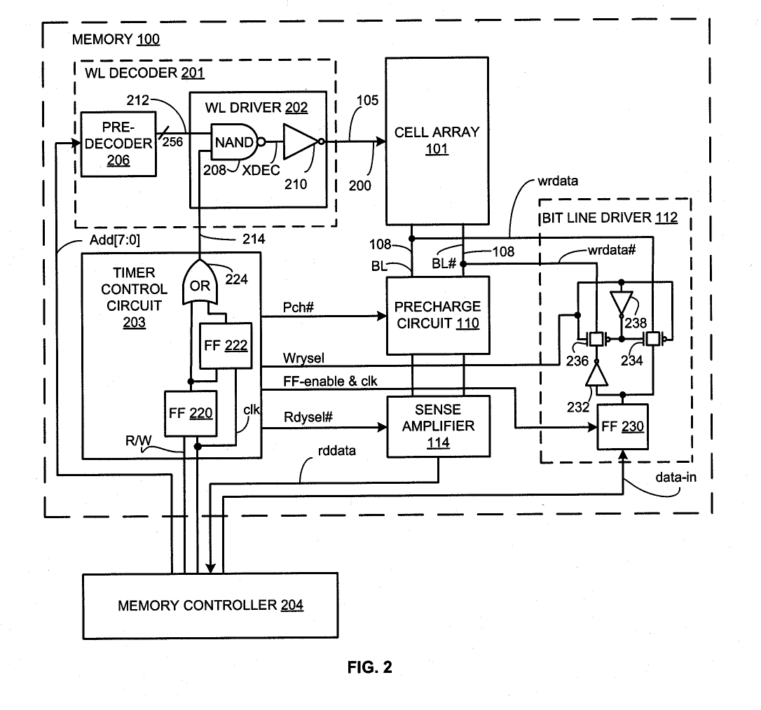

Referring to FIG. 1, there is illustrated a memory 100, according to some embodiments of the present disclosure, having a cell array 101 of SRAM memory cells 102 (hereafter, “cells”). The array 101 of cells 102 may be arranged in rows 103 and columns 104. FIG. 1 is illustrated with a partial showing of 256 cells 102 (labeled as “cell0” through “cell256”); however, various numbers of cells 102 may be includes in array 101. The memory 100 may have a plurality of word-lines 105 (illustrated by word-lines “wl₀” through “wl₂₅₅” in FIG. 1), with one of the word-lines 105 being associated with each of the rows 103 of cells 102. A row address or word-line (WL) decoder 106 may include a plurality of word-line (WL) drivers 107 (only one illustrated), with one of the WL drivers 107 being coupled to an associated one of the plurality of word-lines 105 (e.g., wl₀-wlₙ₋₁). A selected WL driver 107 may be configured to drive the voltage on the selected one of the word-lines 105 with a word-line signal WL. The word-line signal WL may be characterized as being a “write WL signal” or a “read WL signal” to select during a write or a read operation, respectively, one of the rows 103 of cells 102 coupled to the selected one of the word-lines 105. The WL decoder 106 may be responsive to an address (Add) to generate a decoded address signal to cause a selected one of the WL drivers 107 to generate the word-line signal WL. This address is illustrative by an 8 bit address in FIG. 1; however, the number of bits in the address may be dependent upon the number of word-lines 105. One embodiment of the WL driver 107 for an extended write WL signal is illustrated in FIG. 2 and a second embodiment of the WL driver 107 for an extended and boosted write WL signal is illustrated in FIG. 6.

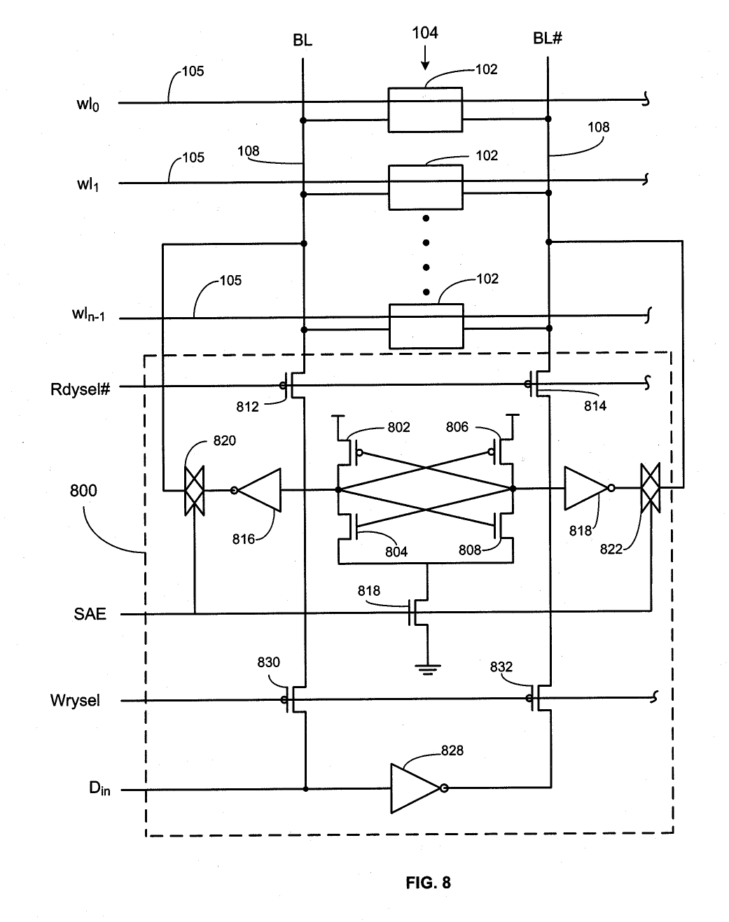

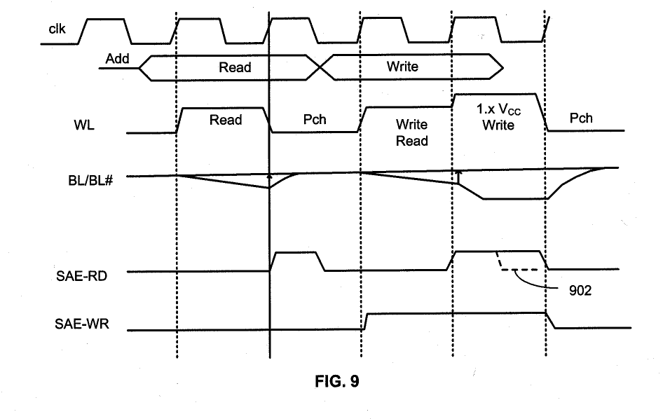

Referring to FIG. 1, the array 10 may include a plurality of bit-lines 108, with a pair of bit-lines (illustrated bit-line BL and complementary bit-line BL# in FIG. 1) being associated with each of the columns 104 of cells 102 of the array 101. A precharge circuit 110 may be coupled between each of the pairs of bit-lines BL and BL# to precharge the bit-lines 108 in response to a precharge signal Pch# prior to a read or write operation. Generally, the bit-lines 108 may be precharged to a high rail voltage level during a time period when the cell 102 is not being accessed. In some embodiments, the memory 100 may be illustrated with a bit-line driver 112 for a write operation and a sense amplifier 114 of a read operation, with both being coupled across each of the pairs of bit-lines BL and BL# of a given column 104 of cells 102. In other embodiments, the bit-line driver 112 and sense amplifier 114 may be combined, as will be shown in FIG. 8.

The bit-line driver 112, in response to receiving write data steam “data-in” and a write-select signal Wrysel, may be used in writing a write-data (“wrdata”) signal and its complement “wrdata#” to the bit-lines BL and BL#, respectively, to write the write-data “wrdata” to a target cell 102 selected by a write WL signal on one of the word-lines 105. The sense amplifier 114 may be used to read a bit of data stored in a target cell 102 selected by a read WL signal on one of the word-lines 105 to produce a read-data output signal “rrdata”, when enabled by a read-select signal Rdysel# applied to gates of pass p-channel metal oxide semiconductor (PMOS) transistors 116 and 118 of the sense amplifier 114. The sense amplifier 114 may detect a small differential signal developed across the pair of bit-lines BL and BL#, and amplify the differential signal into the read-data signal “rrdata”, with the proper logic levels.

In FIG. 1, the memory cell 102 may be illustrated by two inverters 120 and 122 (numerals appear in “cell128”) coupled together at data nodes “n0” and “n1” to form a bistable latch, which may assume one of two possible states, a logical one or a logical zero. With this double-ended SRAM cell 102, the bit-lines BL and BL# may be coupled to the data nodes “n0” and “n1”, respectively. With the illustrated 6 transistor (6T) SRAM cell 102, each of the inverters 120 and 122 may include n-channel metal oxide semiconductor (NMOS) pull-down transistor and a p-channel MOS (PMOS) pull-up transistor, with the four transistors of the inverters 120 and 122 being in a cross-coupled inverter configuration. Two additional NMOS select or pass transistors 124 and 126 may be added to make up the 6T cell, which may be coupled to one of the word-lines 105 via the gates of the transistors 124 and 126. Depending upon the design, application specific SRAM cells 102 may include an even greater number of transistors (e.g., 8T). In other embodiments, the SRAM cells 102 may have fewer transistors, such as resistive load SRAM cells or thin film transistor (TFT) SRAM cells. Although FIG. 1 is illustrated with a differential, six-transistor, double-ended SRAM cell 102 accessed from bit-line pairs BL and BL#, a single-end five-transistor (5T) SRAM cell accessed by a single bit-line also may be used. In this case, the memory cell 102 may be modified to use only a single bit-line 108 so that half of the bit-lines are precharged.

Referring to FIG. 2, the memory 100 of FIG. 1 is shown in more detail and in particular is shown with those component modifications needed to generate an extended write WL signal 200 that extends over substantially two clock cycles. In these embodiments, the generic WL decoder 106 of FIG. 1 becomes a WL decoder 201 in FIG. 2 and the generic WL driver 107 of FIG. 1 becomes a WL driver 202 in FIG. 2. The memory 100 of FIG. 2 may also include a timing control circuit 203 (hereafter, “timer 203”). In some embodiments, the timer 203 may be positioned in the array 101 and may provide internally-generated, memory access control signals for the various components of the memory 100, such as enabling signals for the decoders 201 and 113, precharge circuit 110, and sense amplifier 114. In some embodiments, the timer 203 may use a self-timed approach of generating the enabling signals at the appropriate moments of time in response to the timer 203 automatically detecting address signal transitions on a bus.

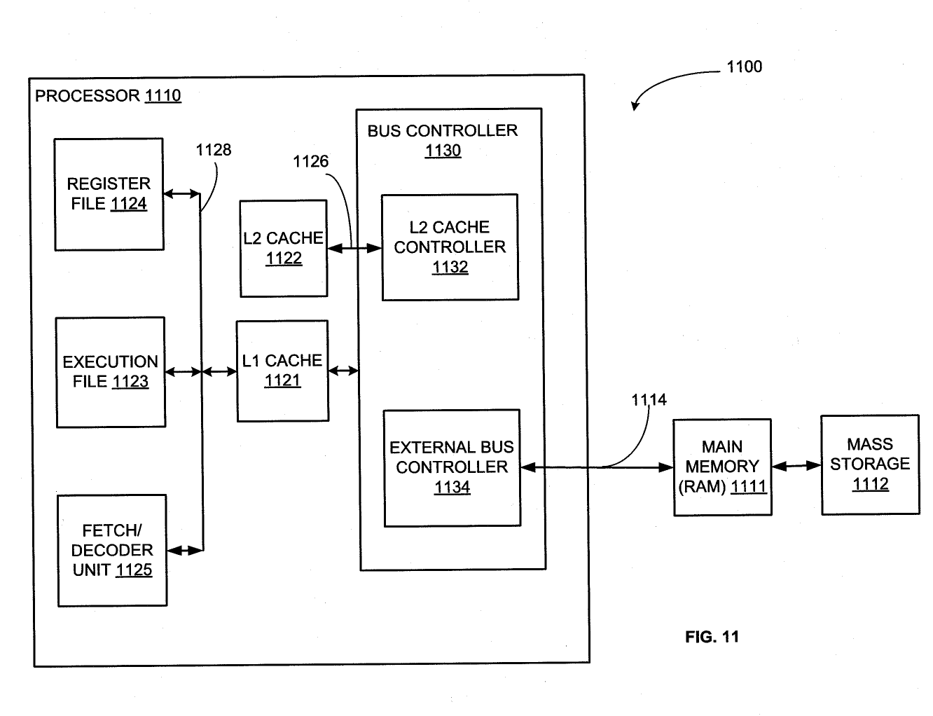

In some embodiments, the timer 203 of the memory 100 may be coupled to a memory controller 204 (see FIG. 11) by way of a bus or the memory controller 204 may be on the same chip as the memory 100. In some embodiments, the controller 204 may provide control signals to the timer 203. For example, the controller 204 may provide the timer 203 a memory-write/memory-read signal “R/W”. In a write operation, the memory-write signal from the controller 204 may request that the timer 203 generate the control signals to cause the write-data “wrdata” on a bus to be written into an addressable location, e.g., the target cell 102. In a read operation, the memory-read signal from the controller 204 may request that the timer 203 generate the control signals to cause the read-data “rddata” from an addressable location, i.e., the target cell, to be placed on a bus. In some embodiments, the controller 204 may provide the timer 203 with the clock signal “clk” having a plurality of clock cycles. In some embodiments, the memory controller 204 may be a cache controller coupled to a processor (see FIG. 11). In other embodiments, the memory controller 204 may be the processor itself

The WL decoder 201 further may include a pre-decoder 206 configured to receive the row address (e.g., Add [0:7]) from an address bus (see FIG. 11) to select a one of a plurality of WL drivers 107 and one of a plurality of associated word-lines 105 (illustrated with 256 word-lines). In some embodiments, each of the WL drivers 107 (only one shown) may include a NAND gate 208, with an output signal XDEC coupled through an inverter 210 to provide the write or read WL signal to a selected word-line 105 selected by the logic of the pre-decoder 206. Each of the WL drivers 107 may have two inputs, a WL-selecting signal 212 from the pre-decoder 206 and a word-line enable signal 214 from the timer 203. The write data stream “data-in” to the bit-line driver 112 may be provided by a data bus. The address bus providing the row address and the data bus providing the data stream “data-in” may or may not be controlled by the memory controller 204. In some embodiments, a column decoder may be included in the timer 203. The column decoder of the timer 203 may provide the read-select signal Rdysel# for selecting a particular column (for example, 1 out of 4 or 8 columns may be selected based on the column decoding and hooked up to the sense amplifier 114). Likewise, the timer 203 may provide a write-select signal Wrysel for selecting a particular column for the write operation (for example, 1 out of 4 or 8 columns may be selected and hooked up to the bit-line driver 112). In other embodiments, the bit-line driver 112 may be included as part of a column decoder separate from the timer 203.

Although the timer 203 generates a number of control signals, the only circuitry shown in the timer 203 is that circuitry added to extend the write WL signal. In some embodiments, the timer 203 may include a first flip-flop 220, which may have an output commonly coupled to the input of a second flip-flop 222 and a first input of an OR gate 224. The second flip-flop 222 may have a clock signal “clk” from the clock source (e.g., memory controller 204) as an input and may have its output coupled to a second input of the OR gate 224. The OR gate 224 may provide the word-line enable signal 214 to all of the WL drivers 107. The two flip-flops 220 and 222 may be in common with all word-lines 105 by being coupled to all the NAND gate 208 of the WL drivers 107 and may extend of the write WL signal. In some embodiments, as will be described hereinafter, the timer 203 may provide a number of other enabling/control signals. For example, the timer 203 may provide the write-select Wrysel signal, a flip-flop enable (FF-enable) signal, and a clock (clk) signal to the bit-line driver 112; the read-select (Rdysel#) signal to the sense amplifier 114; and the precharge (Pch#) signal to the precharge circuit 110.

Referring to FIG. 2, the bit-line driver 112 of FIG. 1 is shown in more detail. The bit-line driver 112 may include a flip-flop 230 to receive the write-data stream “data-in”. The bit-line driver 112, in response to the FF-enable signal, clock signal “clk”, and write-select signal Wrysel from the timer 203, may provide at its output the write-data signal “wrdata”, which may be a single bit of the write-data stream “data-in” to be written into the target cell 102 of FIG. 1. The FF-enable signal may enable the bit-line driver 112 to extend the duration of the write-data signal “wrdata” to be valid for multiple clock cycles, e.g., 2 cycles. The write-data signal “wrdata” and its complement “wrdata#” (output of an inverter 232) may be provided to a pair of transfer gate gates 234 and 236 enabled by the write-select signal Wrysel. The write-select signal Wrysel may be provided to gates of a PMOS transistor and an NMOS transistor of the transfer gates 234 and 236, respectively, and an inverted write-select signal Wrysel# (not shown) may be provided to the gates of a NMOS transistor and a PMOS transistor of the transfer gates 234 and 236 through an inverter 238, respectively. In response to the signal Wrysel, the transfer gates 234 and 236 may apply the write-data signals “wrdata” and “wrdata#” to the bit-lines BL and BL#, respectively. One of the bit-lines 108 (either the positive precharged bit-line BL or the negatively charge bit-line BL#) may be discharged during the write operation to the target cell 102. In some embodiments, the bit-line driver 112 may be included in a column address decoder (see FIG. 1).

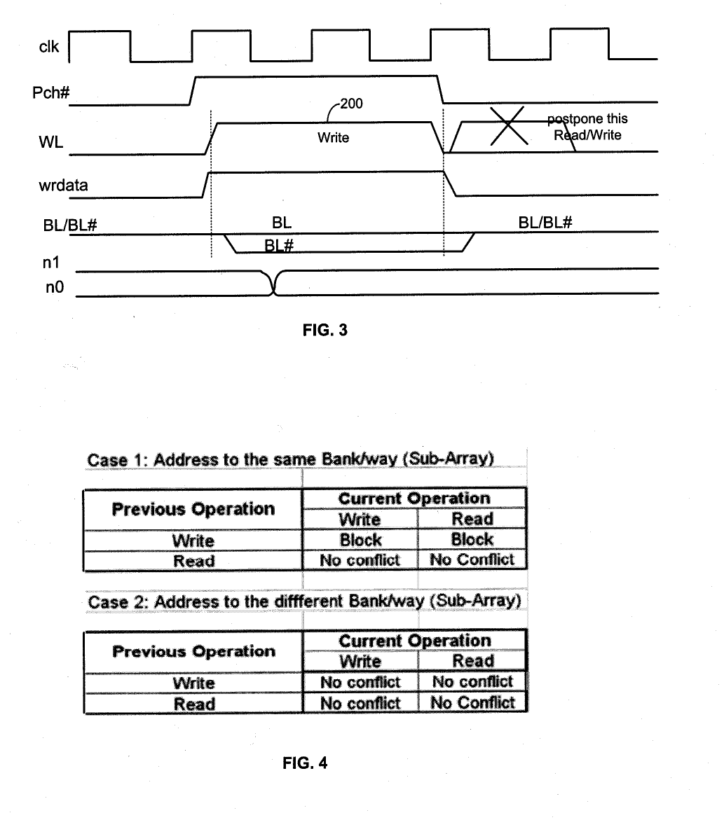

Referring to FIG. 3, a timing diagram for the memory 100 of FIGS. 1 and 2 implementing the write-extension scheme is illustrated, according to some embodiments of the present disclosure. Without the above-described modifications introduced into the WL driver 107 and bit-line driver 112, the memory 100 would have a through-put of 2 clock cycles and write WL signal would ON for the duration of one clock cycle, so back-to-back reads and writes may happen every other clock cycle. The dead clock cycle (every other cycle) between back-to-back read/write operations would be used for precharge where both BL/BL# are brought to the supply voltage V_{CC} to prepare the bit-lines for next operation. Since allowable write time is only 1 clock cycle in this case, this may put a constraint on write V_{MIN} (lowest possible voltage where write can still occur at a given frequency). However, with the modifications illustrated in FIG. 2 to implement the write-extension scheme, the write V_{MIN} may be reduced by extending the write WL signal 200 to about 2 clock cycles (from about the just-described 1 clock cycle) as shown in FIG. 3, with limited or no architectural performance loss.

Referring to FIGS. 1 through 3, the clock signal “clk” in FIG. 3 may be coupled to a number of components shown in FIG. 2 and is shown in FIG. 3 with four clock illustrative cycles. The complement precharge signal Pch# in FIG. 3 may cause the precharge circuit 110 of FIGS. 1 and 2 to precharge the bit-lines BL and BL# during the first illustrated clock cycle and to not precharge during the next two clock cycles, the second and third illustrative clock cycles. This may allow for the write WL signal 200 to extend for almost two clock cycles during the second and third illustrative clock cycles, when there is no precharging. Extending the trailing edge of the write WL signal 200 may be accomplished by adding the second flip-flop 132 and the OR gate 134 to the WL driver 107 as shown in FIG. 2. Alignment of the signal edges of the various waveforms are illustrated by the two vertical dashed-lines in FIG. 3.

Note that in FIG. 3 the extended write WL signal 200 may fall slightly short of a two clock cycle duration; hence, the extended WL signal 200 may be described as having an extended duration of “substantially 2 clock cycles” or “about 2 clock cycles”. In other words, the leading edge of the extended write WL signal 200 may start after the beginning of the second illustrative cycle with a slight delay. More specifically, in FIG. 3 the write WL signal 200 is illustrated with a leading edge transition from Low to High with a small delay after the beginning of the second clock cycle and a trailing edge transition from High to Low beginning at the end of a third clock cycle. More generally, the extended WL write signal 200 may be created by extending its trailing edge from the second illustrative clock cycle into all or a substantial portion of the third clock cycle. In this example, the fourth illustrative cycle may be referred to as a “subsequent clock cycle” in that it occurs subsequently to the two-cycle period (second and third illustrative cycles) for the write WL signal 200. In this example, the precharge of the BL/BL bit-lines may occur in the first and fourth clock cycles.

If the write WL signal had not been extended, and occurred within a second illustrative clock cycle, then the third clock cycle could have been used for precharge and back-to-back write or read operation could have occurred in the fourth cycle. However, because of the extended write WL signal 200 extending over a two cycle period, a request for a back-to-back read or write may be postponed, as indicated on the word-line signal WL waveform by crossing out a read/write WL signal in the fourth illustrative clock cycle, with the fourth illustrative clock cycle instead being used for precharge. Which back-to-back read or write operations are postponed will be described later using FIG. 4.

The write-data signal “wrdata” in FIG. 3 also may have a duration and timing substantially similar to that of the write WL signal 200 by use of the “FF-enable” signal provided to the flip-flop 220 in FIG. 2. The signal “wrdata” in FIG. 3 may be applied to a pair of bit-lines 108 in FIG. 1 to potentially cause a full-swing signal BL/BL# to develop. The BL/BL# signal waveform in FIG. 3 illustrates such a forming of the full-swing signal on the bit-lines 108 of FIGS. 1 and 2, after the bit-lines 108 have been precharged by the precharge signal Pch# in FIG. 3 and in response to the write-data signal “wrdata”, with the full-swing signal BL/BL# also being extended. More specifically, the BL/BL# signal may now develop and extend for about two cycles, before the next precharging by the precharge signal Pch# in the subsequent cycle. The waveforms for the data nodes “n0” and “n1” in FIG. 3 of one of the cells 102 of FIG. 1 are shown transitioning to a new logic state in response to the formation of the full swing signal BL/BL#.

With respect to the write extension scheme of FIGS. 1-3, the memory 100 may be designed to increase write pulse width (PW) without reducing the frequency or the performance of an associated processor (see FIG. 11). In one illustrative embodiment, it was found that the V_{MIN} may be reduced with write extension scheme by approximately 75 mV, but such reductions may change depending on the settings. This in turn may help to have better yields, with most of the benefit actually coming at higher frequencies. Low frequency V_{MIN} reduction using the write-extension scheme may be limited due to reaching the intrinsic write failures of the memory cell 102.

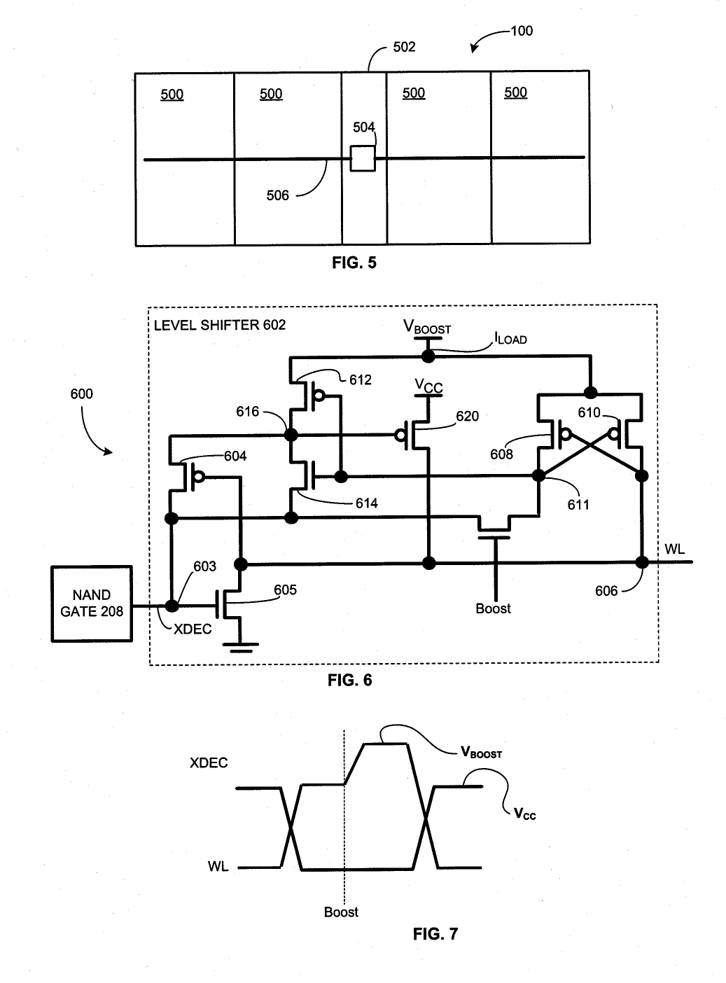

Referring to FIG. 1, to the extent illustrated, the array 101 of memory 100 is shown with all of the word-lines 105 under the control of a single WL decoder 106 (WL decoder 201 in FIG. 2), and if included, all the bit-lines 108 under the control of a single column decoder 113. As mentioned above, a requested back-to-back read or write operation (every other cycle) after an extended write operation may be postponed, as illustrated in FIG. 3 by a marked-out write/read signal on the same word-line 105 in a subsequent clock cycle after the prior write WL signal 200. But any back-to-back access operation using the WL decoder 106 for the subsequent clock cycle after the two-cycle write WL signal 200 may be postponed due to conflicts (all the bit-lines 108 are precharged, conflicting with any back-to-back read/write signals on any of the word-lines 105). In general, when the extended write WL signal 200 and a subsequent, back-to-back access operation are both applied to the smallest memory block where read and write controls (address, data) are shared, then the back-to-back operation may be postponed. In some embodiments, such as illustrated in FIG. 5 (to be discussed hereinafter), the array 101 of memory 100 of FIG. 1 may be illustrative of a sub-array of the memory 100, with the memory 100 having a plurality of sub-arrays 101. Each of the sub-arrays 101 may have the illustrated WL decoder 106 with the plurality of word-lines 105 and the column decoder 113 with the plurality of bit-lines 108. In these embodiments, the smallest memory block where read and write controls (address, data) are shared is the sub-array 101 of memory 100.

Referring to FIG. 4, the possible sub-array conflicts leading to a postponement of a back-to-back write or read operation are illustrated, with the memory 100 of FIG. 1 including a plurality of sub-array or bank memories 101. In these embodiments, rejections of read or write operations may be reduced by only rejecting a read or write operation after a write operation if the subsequent access is to the same sub-array. In other words, the access conflict may happen when the write operation and the read or write operation that immediately follows it, targets the same physical sub-array. Sub-array partitioning may be undertaken based on the address, and thus the potential conflict may be determined by comparing the addresses of the prior write operation with the subsequent, back-to-back write or read operation. As illustrated in Case 1 of FIG. 4, if the same sub-array having the prior write operation is selected (i.e., a read or write address does target a cell within the same sub-array), then the subsequent read or write operation may be rejected and rescheduled later. As illustrated by Case 2 of FIG. 4, if the same sub-array is not selected (i.e., a read or write address does not target a target cell within the sub-array having the prior write operation), the read or write operation in the subsequent cycle may be applied to the appropriate word-line of the different sub-array. In both Case 1 and 2, there are no conflicts after a read operation, since it may be contained within one clock cycle. In some embodiments, any rejection of a subsequent write operation or read operation and rescheduling of the write or read operation may be undertaken by the memory controller 204 of FIG. 2.

In some read-after-write (RAW) embodiments, a potential conflict scenario detected with the above-described address comparison may be further refined with the read hit/miss information when the memory 100 of FIGS. 1 and 2 is used as cache memory, while both the read and the write flows through a cache pipeline. In these embodiments, the memory controller 204 of FIG. 2 may be a cache controller (see FIG. 11). In response to a processor (see FIG. 11) generating an address of a word to be read, the cache controller may determine if the word is contained in the cache memory 100. If it is there, then there is a “hit; if not, then there is a “miss”. Once the real conflict is determined (both write and read targets the same sub-array as determined by the hit/miss information, as both are hitting the cache), a “pipeline reject” may be introduced, while the read operation is in the pipeline, leading to a rejection of the read-after-write. Since the write operation has already been committed to the pipeline, it may be allowed to complete normally—and modify the data in the memory 100. The read operation cannot complete, as the sub-array is still being used by the prior write operation. In some embodiments, this pipeline reject may result in an indication being sent to the cache accesses queue structure (not shown) of the cache controller that the read data coming back for this read operation is invalid and needs to be discarded, and also, this read operation needs to be re-dispatched. With respect to write-after-write (WAW), subsequent write operations may be delayed (postponed) by one cycle (or 2 cycles depending on the ring alignment) so that the extended write signal (or available write time) may be extended to 2 cycles. There is no change for Write after Read (WAR) and Read after Read (RAR) pipeline for any of these embodiments.

As described above, the write-extension scheme implement in FIGS. 1-4, according to some embodiments of the present disclosure, may help to reduce write V_{MIN} at high frequencies, but may provide limited reduction at very low frequencies. To overcome this limitation, in other embodiments, a new technique, Read Modified Write (RMW), may be introduced to reduce write V_{MIN} at low frequencies by using the write WL signal boosting. In some embodiments according to the present disclosure, the write WL signal boosting may be achieved by supplementing the components of the memory 100 of FIG. 1 with an integrated charge pump and a 2 stage level shifter (2SLS). Hence, in some embodiments, the RMW scheme may supplement the write-extension scheme to reduce write V_{MIN} at low frequencies.

Referring to FIG. 5, the memory 100 of FIG. 1, according to some embodiments of the present disclosure, is shown arranged into a plurality of sub-arrays 500. In some embodiments, each of the sub-arrays 500 may take the form of the cell array 101 of FIG. 1. Each of the sub-arrays may be a standalone memory, in that it is physically and electrically isolated from other sub-arrays 500. In other words, each of the sub-arrays 500 may also include the WL decoder 106 of FIG. 1 and other ancillary modules and components used for addresses and data included to the array 101 of FIG. 1. In some embodiments, mid-logic circuitry 502 may included, with such circuitry being shared between sub-arrays 500. In FIG. 5, a charge-pump 504 is positioned in the mid-logic 502 and may be shared across the different sub-arrays 500.

Referring to FIG. 5, the cell array 101 may be illustrated with four sub-arrays 500 and connection lines 506, with the charge pump 504 being shared with the four sub-arrays 500 by way of the connection lines 506. The shared charge pump 504 may result in reduced area and power overheads. The charge pump 504 may consume extra power to provide V_{BOOST}. However, since only one word-line may be active out of so many in the 4 sub-arrays example, this power may be amortized across all the word-lines. In one illustrative example of a 2 MB memory cache, there may be over 16,000,000 memory cells 102 of FIG. 1. These may be divided into 10 banks, each of which has 10 sub-arrays 500. Each sub-array 500 may have 256 columns, and each column may have 512 individual memory cells. The particular number of cells and the particular division of the cells among columns, arrays, blocks or any other grouping elements may depend upon the particular application to which the memory 100 of FIG. 1 is to be applied. The 2 MB cache is provided only as an example.

Referring to FIG. 6, the memory 100 of FIGS. 1 and 5, according to some embodiments of the present disclosure, may be modified as follow to generate an extended and boosted write WL signal. The WL driver 107 of FIG. 1 may become a WL driver 600 in FIG. 6. The WL driver 600 may include a 2-stage level shifter 602. The WL driver 600 is the same as the WL driver 202 of FIG. 2 except the level shifter 602 may replace the inverter 210 of FIG. 2. Hence, the level shifter 602, as part of the WL driver 107 of FIG. 1, may be repeated for each of the word-lines 105 of FIG. 1. Additionally, the timer 203 of FIG. 2 may be modified to generate an additional signal, a Boost signal, which is provided to the level shifter 602. All of the remaining components of the memory 100 of FIGS. 5 and 6 remain the same as shown in FIGS. 1 and 2; hence, they are not repeated herein.

The level shifter 602 may be configured to generate a two clock cycle write WL signal having at the operating voltage V_{CC} (first voltage) during the first clock cycle and a boosted voltage V_{BOOST} (second voltage) in the second clock cycle. Hence, the write WL signal may have a voltage step in transitioning from the first, lower voltage V_{CC} to the second, higher voltage V_{BOOST}. The operating voltage V_{CC} is the voltage V_{MIN} or V_{CCMIN} and is an externally-provided supply voltage for the memory 100 of FIG. 1. The boosted voltage V_{BOOST} is provided by the charge pump 504 of FIG. 5. In the first stage of the level shifter 602, the level shifter 602 may transition from “0” to V_{CC} and in a second stage, may supply the remaining V_{CC} to V_{BOOST}.

The level shifter 602 may reduce the dynamic I_{LOAD} current that needs to be supplied by the high supply charge pump 504 of FIG. 5. In one example, the RMW scheme using this level shifter 602 may help to improve low frequency V_{MIN} by as much as 250 mV for a low voltage memory cell 102 of FIG. 1. This may also help drive the overall V_{CCMIN} of the small signal arrays (SSAs) on chip dies even lower and thereby may achieve lower average power for a system, which in turn may result in a smaller/inexpensive cooling solution and therefore may reduce overall costs.

Referring to FIG. 6, the signal XDEC from the NAND gate 208 may be provided at an input node 603 of the level shifter 602, which in turn is coupled to a drain of a PMOS transistor 604 and to a gate of an NMOS transistor 605. The transistor 605 may have a source coupled to ground (V_{SS}) and a drain coupled both to the gate of transistor 604 and to an output node 606 providing the word-line signal WL. The voltage V_{BOOST} may be coupled to the sources of a pair of PMOS transistors 608 and 610 with their gates cross-coupled to the drains of transistors 608 and 610, with the transistors 608 and 610 forming the half-latch. The drain of transistor 608 is shown connecting to a node 611. An inverter including PMOS transistor 612 and NMOS transistor 614 may have an output node 616 coupled to the source of the PMOS transistor 604 and may have an input (gates of transistors 612 and 614) coupled to the node 611. The source of transistor 614 of the inverter may be coupled to the drain of the transistor 604 and to a pass NMOS transistor 618, which is also coupled to the node 611. The operating voltage V_{CC} may be coupled through a pass PMOS transistor 620 to the output node 606. The transistor 620 may have its gate coupled to the output node 616. A pass NMOS 622 may be coupled between the input node 603 and the node 611 and receive a Boost signal at its gate to turn on, with the Boost signal originating from a timer 203 of FIG. 2 after a pre-set time. The pre-set time may be selected so that V_{BOOST} is maintained during at least a substantial portion of the second cycle of the two-phase write WL signal. In some embodiments, every signal generated by timer 203 or WL decoder 106 may be a low V_{CC} signal. This may simplify the timer/decoder design. The contention in the level shifter 602 may be reduced by a half-latch and input interruption feature.

Referring to FIGS. 6 and 7, in operation, the pass transistor first phase (“0”-to-V_{CC}) may be supplied by the pass transistor 620, at which point, the PMOS transistor 610, in response to the Boost signal at the transistor 622, may kick in to supply the second phase (V_{CC}-to-V_{BOOST}). More specifically, as the signal XDEC transitions from V_{CC} to V_{SS} (see FIG. 7), the inverter output node 616 may transition from V_{BOOST} to V_{SS}, and the output node 606 may transition from V_{SS} to V_{CC}. Upon receiving the Boost signal at the transistor 622 from the timer 505 of FIG. 5, the inverter output node 616 may transition from V_{SS} to V_{BOOST}, the node 611 may transition from V_{CC} to V_{SS}, and the output node 606 may transition from V_{CC} to V_{BOOST}. During the second clock cycle, the write WL signal may be boosted to V_{BOOST} for write-ability improvement. The write WL signal boosting may reduce the contention while also improving write-completion process by writing from both sides of the memory cell 102. Also, unlike the V_{CC}-collapse scheme, the boosted WL signal may not affect the retention of the unselected cells on the same column 104 of memory cells 102.

In other embodiments, where V_{CC}=V_{MAX} (the maximum possible voltage for the system), boosting may not be possible due to transistor's gate-oxide and/or junction reliability constraints, so the RMW scheme may be disabled and instead a limited V_{CC}-collapse in the first cycle is applied if needed (that is, if the cell is un-writable when V_{CC}=V_{MAX}). In some illustrative simulation results, there was a 40 mV improvement in the smallest SRAM cell write V_{CCMIN} (from 0.91V to 0.87V) by simple stretching of the write WL signal from 1 to 2 cycles with diminishing returns for further stretching. On the other hand, RMW scheme with 1.6× boosting on the 2nd cycle gave approximately 250 mV of V_{CCMIN} improvement (from 0.87V to 0.62V).

A memory write-back approach involves writing data back into a cell after it has been read. The basic idea is to allow the cell to be unstable and upon a read operation, the cell value is read using a per-column sense-amplifier and then written back to correct for any possible flipping. Thus cell read failure criterion may depend on the cell's inability to develop enough differential before it actually flips. In essence, the read operation may be allowed to be destructive.

Referring to FIGS. 6 and 7, in some embodiments, boosting the WL voltage during second cycle may or may not affect the stability of the cells on unselected columns experiencing dummy-reads. In some embodiments, if write WL signal boosting does not affect the dummy read cell stability, then a per-column sense amplifier (SA) may not be needed to perform the above-described write-back operation. In other embodiments, if the write WL signal boosting affects the dummy-read stability, then a per-column SA, such as the one illustrated in FIG. 8, may be used in the memory 100 of FIG. 1. In this case, first cycle may be used to read all dummy reads while the selected bits for write start their write operations. Per-column synchronous SAE may be used to write all dummy reads in the second cycle. Additionally, a pulsed SAE signal may be useful for partial write-back and to reduce bit-line power dissipation as compared to full-swing bit-line write-back. Hereafter, the per-column sense amplifier of FIG. 8 will be described, with that sense amplifier being utilizable in place of the sense amplifier 114 of FIG. 1.

Referring to FIG. 8, those components that remain the same as in FIG. 1 utilize the same reference numbers. A sense amplifier and write driver (sense amp/write driver) 800 is illustrated, which may be shared across memory sectors. In addition to reading data, the sense amp/write driver 800 may be used as a write or bit-line driver (eliminating the need for the bit-line driver 112 of FIG. 1) and therefore the actual write-driver size may be reduced. A single column 104 of memory cells 102 are illustrated, with the same word-lines 105 (e.g., wl₀-wlₙ₋₁) and bit-lines 108 (e.g., BL and BL#) as shown in FIG. 1. The sense amp/write driver 800 may have cross-connected pair inverters, including a first inverter (PMOS and NMOS transistors 802 and 804) and a second inverter (PMOS and NMOS transistors 806 and 808). Hence, in some embodiments, the sense amp/write driver 800 may have the same configuration as a SRAM cell. As in FIG. 1, the read-select signal Rdysel# may be coupled to the gates of a pair of PMOS transistors 812 and 814, so as to couple the data nodes of the sense amp/write driver 800 to the pair of bit-lines BL and BL#. Additionally, the data nodes of the sense amp/write driver 800 may be coupled through pairs of inverters 816 and 818 and transfer gates 820 and 822 to the bit-lines BL and BL#, respectively. The sources of the NMOS transistors 804 and 808 may be coupled to ground through a pass NMOS transistor 819 having a gate coupled to a sense amplifier enable (SAE) signal. The pair of transfer gates 820 and 822 may also be coupled to the SAE signal, which, when enabled, may allow the signal on the bit-lines BL and BL# to appear on the data nodes to be read after passing through inverters 816 and 818, respectively. A data-in signal (Din) and its complement generated by an inverter 828, may be coupled to the source of NMOS transistors 830 and 832. A write-select signal Wrysel may be coupled to the gates of the transistors 830 and 832.

Referring to FIG. 9, a timing diagram for the memory 100 of FIG. 1 using the sense amp/write driver 800 of FIG. 8 is described. The clock signal “clk” may be provided by an off-chip clock source. In an illustrative example, an address bus (not shown), coupled to the input of the WL decoder 106 of FIG. 1 is shown with a READ address signal, followed by a WRITE address signal. With respect to the word-line signal WL waveform, a read operation signal may be generated on the appropriate word-line 105 during a given clock cycle, followed by a clock cycle during which the bit-lines BL and BL# may be precharged. With respect to the word-line signal WL waveform, after the cycle for precharging, as with the write-extension scheme, this boost scheme may have the write operation extending over about two cycles, with the write WL signal being boosted in the second cycle, as illustrated in the WL waveform of FIG. 7. With respect to the BL/BL# waveform, the signal BL/BL# may be a greater voltage in the second cycle than the first cycle. Therefore, extending the full-swing signal BL/BL# substantially over a two-cycle period may allow the differential voltage on the bit-lines to increase and therefore may reduce the probability of cell upset.

A per-column synchronous SAE-RD (sense amplifier enable signal-read) signal may be used to enable the sense amp/write driver 800 of FIG. 8 to enable a read operation on the same column used for the subsequent WRITE operation request (referred to as a WR-selected column). The SAE-RD signal also shows the SAE-read enable signal applied to a different, dummy-read column to read all the dummy-reads during the two-cycle write operation on a WR-selected column, with the dummy-read column being a different column form the WR-selected column. In some embodiments, the SAE-RD may be turned off prior to the completion of two-cycle write operation as showed by the dashed line 902, so as to conserve power. A SAE-WR signal may be used to enable the sense amp/write driver 800 during the two cycles for the write operation (write WL signal) shown in the word-line signal WL waveform. In another example, the first cycle of the two write cycles for the write WL signal may be used to read dummy reads, while the selected bits for write start their write operations. A pulsed SAE-RD may be useful for partial write-back using the dummy reads, thereby reducing the bit-line power dissipation as compared to full-swing bit-line write-back. The arrows in the signal BL/BL# illustrate the extent of the signal BL/BL# generated without the extended write signal.

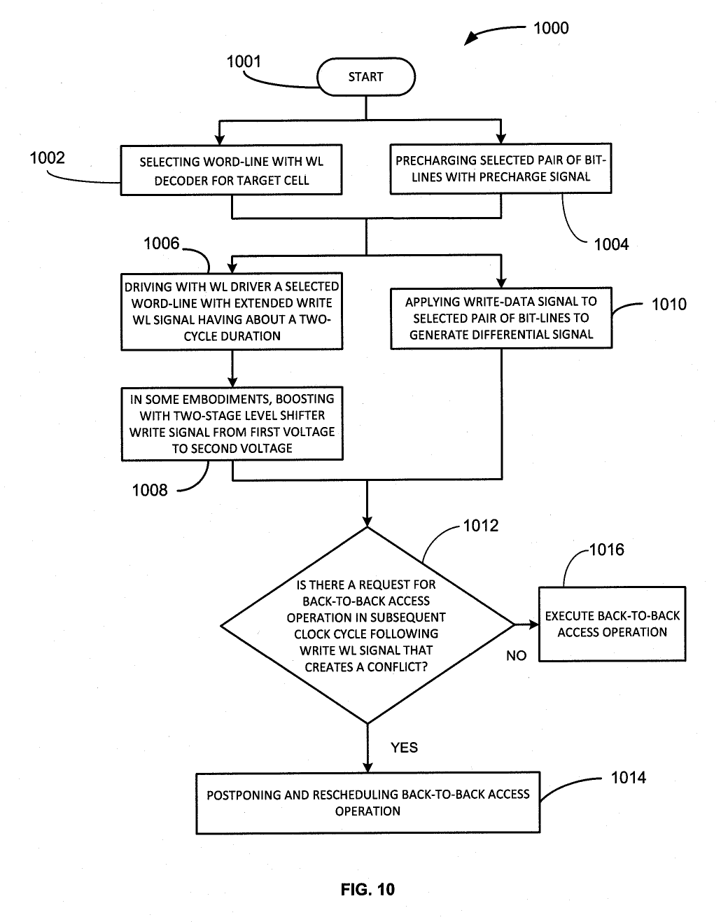

Referring to FIG. 10, there is illustrated an exemplary method 1000 of operating an SRAM memory cell 102 of FIG. 1 during a write operation, in accordance with various embodiments of the present disclosure. In some embodiments, the write operation may be followed with a request for a back-to-back write or read operation. Referring to FIGS. 1 and 10, the method 1000 may start at 1001 with addressing operation 1002 and precharging operation 1004. The addressing operation 1002 may include selecting a word-line 105 with the WL decoder 106, in response to a row address, for a target cell 102 to which a bit of data (wrdata) is to be written. In some embodiments, the addressing operation also may include selecting with the column decoder (e.g., may or may not be part of the timer 203 of FIG. 2) one of a plurality of columns and therefore selecting one of a plurality of pairs of bit-lines 108. The precharging operation 1004 may include precharging the selected pair of bit-lines with a precharge signal during a first clock signal. In some embodiments, the operations 1002 and 1004 may occur in parallel as shown in FIG. 10 (while the bit-lines are precharged, the WL decoder 107 of FIG. 1 may work on decoding the address lines to find out which word-line 105 of FIG. 1 is to be driven high in the next cycle). After the precharging, a row-access operation 1006 may include driving with the WL driver 107 the selected word-line 105 with an extended write WL signal. The write WL signal may have about a two-cycle duration which substantially includes a second and a third clock period.

In some embodiments, the voltage level (V_{CC} after transition) of the write signal on the word-line 105 may remain substantially the same over the second and third cycles. In other embodiments, a boosting operation 1008 may include boosting with a two-stage level shifter in the WL driver 107 the write signal from a first voltage to a second voltage so as to have a voltage step, with the second voltage being higher than the first voltage. In other words, the boosting operation 1008 may include elevating or raising an initial, lower-voltage word-line voltage V_{CC} during at least a part of or all of the third cycle to a higher-voltage word-line voltage (V_{BOOST} after transition). The write signal may be characterized as making the cells 102 in a selected row available for an extended write operation during the substantially two-cycle period, with one of those cells in the selected row being the target cell 102 coupled to the selected pair of precharged bit-lines 108.

Also after the precharging, a differential signal generating operation 1010 may include applying the write data signal “rwdata” to the pairs of precharged bit-lines 108 for an extended period of time, with a duration substantially the same as that of the write signal WL to generate a differential signal between the pair of bit-lines 108. The operation 1010 may include changing the state of the cell 102 in response to the differential signal reaching a predetermined level.

In an conflict checking operation 1012, in some embodiments, the memory controller, in the form of a cache controller (see FIG. 11) or like control circuitry, may check to see if there is an access request for a write or read operation in a fourth cycle. If yes, then in some embodiments, in an operation 1014 the back-to-back access operation may be postponed and re-scheduled later by the memory controller (e.g., cache controller) or like circuitry. In other embodiments having a plurality of sub-arrays, the cache controller may check and see if the address of the back-to-back write or read operation is for the same sub-array as the prior write operation. If yes in these embodiments, then the back-to-back access operation may be rejected in operation 1014. In some embodiments, a pipeline reject signal may be generated by the cache controller and the back-to-back signal may be rejected while still in the pipeline access for the cell array. If there is no conflict, then in an operation 1016 the back-to-back access operation may be executed. In other embodiments wherein the memory 100 is not used as cache memory, then different control circuitry may be used.

Referring to FIG. 11, a computer system 1100 implementing a multiple cache arrangement is shown. A processor 1110 may be coupled to a main memory 1111 by a system bus 1114 and the memory 1111 may then be coupled to a mass storage device 1112. In the example of FIG. 11, two separate cache memories 1121 and 1122 are shown. The caches 1121-1122 are shown arranged serially and each may be representative of a cache level, referred to as Level 1 (L1) cache and Level 2 (L2) cache, respectively. Furthermore, the L1 cache 1121 and the L2 cache 1122 are shown as part of the processor 1100. The actual placement of the various cache memories is a design choice or dictated by the processor architecture. Thus, the L1 and L2 caches or the L2 cache could be placed external to the processor 1110.

Generally, processor 1110 may include an execution unit 1123, register file 1124 and fetch/decoder unit 1125. The execution unit 1123 is the processing core of the processor 1110 for executing the various arithmetic (or non-memory) processor instructions. The register file 1124 is a set of general purpose registers for storing (or saving) various information needed by the execution unit 1123. There may be more than one register file in more advanced systems. The fetch/decoder unit 1125 may fetch instructions from a storage location (such as the main memory 1111) holding the instructions of a program that will be executed and may decode these instructions for execution by the execution unit 1123. In more advanced processors utilizing pipelined architecture, future instructions may be prefetched and decoded before the instructions are actually needed so that the processor is not idle waiting for the instructions to be fetched when needed.

The L2 cache 1122 may be coupled to a backside bus 1126. The various units 1123-1125 of the processor 1110 may be coupled to an internal bus structure 1128. The L1 cache may be coupled between the internal bus 1128 and a bus controller 1130. The caches may be used to cache data, instructions or both. In some systems, the L1 cache actually may be split into two sections, one section for caching data and one section for caching instructions. The bus controller 1130 may provide control logic and interfaces for coupling the various units of processor 1110 to the buses 1114 and 1126. More specifically, the bus controller 1130 may include an L2 cache controller 1132 coupled to the backside bus 1126 and an external bus controller 1134 coupled to the system bus 1114. In other embodiments, where the L2 cache 1122 is on a separate chip, the L2 cache controller 1132 may be included on the chip having the L2 cache 1122.

In this illustrative embodiment, the L2 cache 1122 may comprise the memory 100 of FIG. 1, which is the last level cache in this example. However, the use of the memory 100 of FIG. 1 may be extended to other caches (e.g., L1 or L3 cache) as well. A memory controller 204 of FIG. 3 may take the form of the cache controller 1132. More specifically, the cache controller 1132 may be used in the previously described embodiments of FIGS. 1-10 when the L2 cache 22 includes the memory 100 of FIG. 1. However, the memory controller 204 of FIG. 3 may take different forms, and FIG. 11 illustrates only one example. The L2 cache controller 1132, under the control of the processor 1110, may provide access to the L2 cache memory 1122. For example, with respect to read and write operations initiated by the processor 1100, the L2 cache controller 1132 may reject the read or write operation targeted for the subsequent clock cycle following the extended write WL signal. In one example, the L2 cache controller 1132 may have a cache access queue (not shown) under its control for write and read operations to be executed in the L2 cache 1122. The L2 cache controller 1132 also may reschedule any rejected read or write operation rejected by the L2 cache controller 1132 due to a conflict. In some embodiments, the controllers 1132 and 1134 may communicate with each other. For example, the L2 cache controller 1132 may process a request of L2 information received from the external bus controller 1134.

It is also to be noted that the computer system may be comprised of more than one processor. In such a system, an additional processor bus, coupled to the main bus 1114, may be included and multiple processors may be coupled to the processor bus and may share the main memory 1111 and/or mass storage unit 1112. Accordingly, some or all of the caches associated with the computer system may be shared by the various processors of the computer system. For example, with the system of FIG. 11, L1 cache 1121 of each processor may be utilized by its processor only, but the L2 cache 1122 may be shared by all of the processors of the system. In addition, each processor may have an associated L2 cache 1122. As noted, only two caches 1121-1122 are shown. However, the computer system need not be limited to only two levels of cache. In some embodiments, a third level (L3) cache in more advanced systems. In one illustrative embodiment, an L3 cache may be coupled between the processor bus (not shown) and the main system bus 1114, with multiple processors (not shown) being coupled to the processor bus.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present disclosure. Therefore, it is manifestly intended that this disclosure be limited only by the claims and the equivalents thereof.

What is claimed is:

1. An apparatus, comprising:
a memory array of static random access memory (SRAM) cells arranged in a plurality of rows and a plurality of columns and configured to receive a clock signal having a plurality of clock cycles;
a plurality of word-lines associated with the plurality of rows of the SRAM cells; and
a selected word-line driver configured during an extended write operation to drive a selected one of the plurality of word-lines with a write word-line signal having an extended duration.

2. The apparatus according to claim 1, wherein the selected word-line driver includes a two-stage level shifter configured to generate the write word-line signal with a voltage step from a first voltage to a second voltage; the second voltage being higher than the first voltage.

3. The apparatus according to claim 2, wherein the extended duration includes two clock cycles, and wherein
the two clock cycles include a first clock cycle and a second clock cycle following the first clock cycle; and
the two-stage level shifter is further configured to generate the first voltage substantially during the first clock cycle and the second voltage substantially during the second clock cycle.

4. The apparatus according to claim 2,
wherein the memory array includes a plurality of sub-arrays, with each of the sub-arrays including the plurality of rows and columns of SRAM cells; and
further comprising:
each of the plurality of sub-arrays including a plurality of word-line drivers, with each of the plurality of word-line drivers including one of a plurality of two-stage level shifters; and
a charge pump coupled to the plurality of two-stage level shifters of the plurality of sub-arrays and configured to provide the first and the second voltages to the plurality of two-stage level shifters.

5. The apparatus according to claim 1,
further comprising:
a plurality of bit-lines associated with the plurality of columns of the SRAM cells;
a bit-line driver configured to drive at least one of the bit-lines with a write-data signal substantially during the extended duration to generate a differential signal; and
a precharge circuit configured to precharge the plurality of bit-lines during the subsequent cycle after the extended duration; and
wherein the at least one bit-line is coupled to a selected column of the SRAM cells which includes a target cell; and the target cell is further coupled to the selected one of the plurality of word-lines.

6. The apparatus according to claim 5, further comprising:
a per-column sense amplifier coupled to the at least one the bit-line associated with one of the columns of memory cells; and
the per-column sense amplifier configured to sense the differential signal on the at least one bit-line in response to a pulsed sense-amplifier-enable signal and to generate a read-data signal from the differential signal.

7. The apparatus according to claim 1, further comprising:
a memory controller configured to generate a memory write signal for the extended write operation;
a timer coupled to the memory controller and the selected word-line driver to provide a word-line enable signal to the selected word-line driver in response to the memory write signal;
a row address decoder including a plurality of word-line drivers coupled to the plurality of word-lines and configured to select the selected word-line driver from the plurality of word-line drivers in response to a row address;
the selected word-line driver is configured to generate the write word-line signal on the selected word-line in response to the word-line enable signal; and
wherein the memory controller is further configured to postpone a subsequent write or read operation from generating a subsequent word-line signal in a subsequent clock cycle following the extended duration of the write word-line signal.

8. The apparatus according to claim 7, wherein
the memory array includes a plurality of sub-arrays, with each of the sub-arrays including the plurality of rows and columns of SRAM cells and having a sub-array address; and
the memory controller is further configured to postpone the subsequent the subsequent read or write operation if a sub-array address associated with the subsequent read or write operation is the same as a sub-array address associated with the extended write operation.

9. The apparatus according to claim 7, wherein
the memory array includes a plurality of sub-arrays, with each of the sub-arrays including the plurality of rows and columns of SRAM cells;
the memory controller is further configured to generate a pipeline reject signal if a subsequent read operation targets the same one of the sub-arrays as the extended write operation; and
the memory controller, in response to the pipeline reject signal, is further configured to discard read data generated by the read operation in the subsequent clock cycle and to re-dispatch the read operation in a clock cycle after the subsequent clock cycle.

10. A method, comprising:
receiving a clock signal having a plurality of clock cycles in a memory array of static random access memory (SRAM) cells arranged in a plurality of rows and a plurality of columns, with the plurality of rows being associated with a plurality of word lines; and
during a write operation, driving with a word-line driver a selected one of the plurality of word-lines with a write word-line signal having an extended duration.

11. The method according to claim 10, further comprising:
boosting with a two-stage level shifter in the word-line driver the write word-line signal from a first voltage to a second voltage so as to have a voltage step, with the second voltage being higher than the first voltage.

12. The method according to claim 11, wherein the extended duration includes two clock cycles, and wherein the two clock cycles include a first clock cycle and a second clock cycle following the first clock cycle; the first voltage of write word-line signal occurs substantially during the first clock cycle; and the second voltage of the write word-line signal occurs substantially during the second clock cycle.

13. The method according to claim 10, further comprising:
postponing a write or a read operation in a subsequent clock cycle following the extended duration.

14. The method according to claim 10, wherein the memory array with a plurality of sub-arrays, with each of the sub-arrays including the plurality of rows and columns of SRAM cells; and the method further comprising:
postponing a write or read operation in a subsequent clock cycle following the extended write operation if the read or write operation has an associated sub-array address that is the same as an associated sub-array address for the extended write operation.

15. The method according to claim 10, wherein the memory array includes a plurality of sub-arrays, with each of the sub-arrays including the plurality of rows and columns of SRAM cells; and the method further comprising:
generating a pipeline reject signal if a read operation for a subsequent clock cycle after the extended duration targets the same one of the sub-arrays as the extended write operation; and
discarding by the memory controller read data coming back from the read operation in response to the pipeline reject signal; and
re-dispatching the read operation in a clock cycle after the subsequent clock cycle.

16. A system, comprising:
a processor;
at least one storage coupled to the processor;
the storage including a memory array of static random access memory (SRAM) cells arranged in a plurality of rows and a plurality of columns and configured to receive a clock signal having a plurality of clock cycles;
a plurality of word-lines associated with the plurality of rows of the SRAM cells; and
a selected word-line driver configured during an extended write operation to drive a selected one of the plurality of word-lines with a write word-line signal having an extended duration s.

17. The system according to claim 16, wherein the selected word-line driver includes a two-stage level shifter configured to generate the write word-line signal with a voltage step from a first voltage to a second voltage; the second voltage being higher than the first voltage.

18. The system according to claim 17, wherein the extended duration includes two clock cycles, and wherein
the two clock cycles include a first clock cycle and a second clock cycle following the first clock cycle; and
the two-stage level shifter is further configured to generate the first voltage substantially during the first clock cycle and the second voltage substantially during the second clock cycle.

19. The system according to claim 16, further comprising:
a memory controller configured to generate a memory write signal for the extended write operation;
a timer coupled to the memory controller and the selected word-line driver to provide a word-line enable signal to the selected word-line driver in response to the memory write signal;
a row address decoder including a plurality of word-line drivers coupled to the plurality of word-lines and configured to select the selected word-line driver from the plurality of word-line drivers in response to a row address;
the selected word-line driver is configured to generate the write word-line signal on the selected word-line in response to the word-line enable signal; and
wherein the memory controller is further configured to postpone a subsequent write or read operation from generating a subsequent word-line signal in a subsequent clock cycle following the extended duration of the write word-line signal.

20. The system according to claim 16, wherein
the memory array includes a plurality of sub-arrays, with each of the sub-arrays including the plurality of rows and columns of SRAM cells and having a sub-array address; and
the memory controller is further configured to postpone the subsequent the subsequent read or write operation if a sub-array address associated with the subsequent read or write operation is the same as a sub-array address associated with the extended write operation.
